(19) United States
(12) Patent Application Publication
(10) Pub. No.: US 2014/0026809 A1
(43) Pub. Date: Jan. 30, 2014

(54) Process for Producing Group 13 Metal Nitride, and Seed Crystal Substrate for Use in Same

(71) Applicant: NGK INSULATORS, LTD., Aichi-prefecture (JP)

(72) Inventors: Makoto Iwai, Kasugai-city (JP); Takanao Shimodaira, Nagoya-city (JP); Shuhei Higashihara, Nagoya-city (JP); Takayuki Hirao, Nagoya-city (JP); Masahiro Sakai, Nagoya-city (JP); Katsuhiro Imai, Nagoya-city (JP)

(73) Assignee: NGK INSULATORS, LTD., Aichi-prefecture (JP)

(21) Appl. No.: 14/028,841

(22) Filed: Sep. 17, 2013

Related U.S. Application Data
(63) Continuation of application No. PCT/JP2012/057668, filed on Mar. 16, 2012.

(30) Foreign Application Priority Data
Mar. 18, 2011 (JP) 2011-061332

(51) Int. Cl. C30B 29/40; C30B 9/12

(52) U.S. Cl. CPC C30B 29/403; C30B 9/12
USPC 117/78; 428/141

(57) ABSTRACT

A seed crystal substrate 10 includes a supporting body 1, and a seed crystal film 3A formed on the supporting body 1 and composed of a single crystal of a nitride of a Group 13 metal element. The seed crystal film 3A includes main body parts 3a and thin parts 3b having a thickness smaller than that of the main body parts 3a. The main body parts 3a and thin part 3b are exposed to a surface of the seed crystal substrate 10. A nitride 15 of a Group 13 metal element is grown on the seed crystal film 3A by flux method.

### TECHNICAL FIELD OF THE INVENTION

The present invention relates to a method for producing Group 13 metal nitrides and seed crystal substrates used in the same.

### BACKGROUND ARTS

Gallium nitride (GaN) thin film crystal draws attention as excellent blue light-emitting devices, has been used as a material for light-emitting diodes and expected as a blue-violet semiconductor laser device for an optical pickup. Recently, it draws attention as a semiconductor layer constituting electronic devices, such as high-speed IC chips, used for mobile phones or the like.

It is reported a method of obtaining a template substrate by depositing a seed crystal layer, such as GaN or AlN, on a single crystal body such as sapphire and of growing gallium nitride single crystal on the template substrate. In the case that, however, the gallium nitride (GaN) seed crystal layer is grown on the body by vapor phase process by MOCVD and the gallium nitride single crystal is grown thereon by flux method, cracks are generated in the thus grown single crystal thick layer due to the difference of thermal expansion. For preventing the cracks, it is thus drawn attention the technique of reducing stress applied on the single crystal and of preventing the cracks, by spontaneously peeling the thus grown single crystal from the body.

According to WO 2011/001830 A1 and WO 2011/004904 A1, a seed crystal film made of gallium nitride single crystal is formed on a surface of a supporting body of sapphire or the like, and the seed crystal film is then etched to partly expose the surface of the supporting body so that the seed crystal film is patterned, and gallium nitride is then grown on the seed crystal film by flux method. Further according to Japanese Patent Publication No. 2009-120465A, although the surface of the supporting body is exposed between the seed crystal films, gallium nitride is grown by HVPE method.

According to Japanese Patent No. 4,016,566B, a buffer layer is formed on a supporting body, a seed crystal film is then formed on the buffer layer, and the seed crystal film is patterned so that the buffer layer is exposed between the adjacent seed crystal film.

According to Japanese Patent Publication No. 2004-247711A, a seed crystal film of gallium nitride single crystal is formed on a supporting body, recesses are formed on the side of a surface of the seed crystal film, masks are formed in the recesses, and gallium nitride single crystal is then grown on the seed crystal film by flux method.

According to Japanese Patent Publication No. 2010-163288A, a surface of a supporting body is patterned to form pattern including protrusions, seed crystal films made of gallium nitride single crystal are formed on the protrusions, and a polycrystalline films are formed in a recess between the protrusions. Gallium nitride single crystal is then grown on the seed crystal films by flux method.

### DISCLOSURE OF THE INVENTION

According to a seed crystal substrate having the structure that a material, such as sapphire, of a supporting body is exposed in gaps between seed crystal films, since it is easier to form spaces over the gaps, the grown single crystal is easily separated from the supporting body due to the spaces. It is, however, difficult to grow the gallium nitride single crystal on the seed crystal stably by flux method and many growth defects tend to be generated.

On the other hand, according to the structure that sapphire is not exposed and instead the buffer layer or polycrystalline film is exposed in the gaps between the seed crystal films, the spaces tend to be not generated under the grown single crystal. It is thus difficult to separate the grown single crystal from the supporting body.

An object of the present invention is, in producing a nitride of a Group 13 metal element by flux method using a seed crystal substrate, to prevent growth defects of the nitride of a Group 13 metal element and to enable the separation of the grown nitride of a Group 13 metal element from the supporting body with ease.

The present invention provides a method of producing a nitride of a Group 13 metal element by flux method using a seed crystal substrate. The seed crystal substrate includes a supporting body, and a seed crystal film formed on the supporting body and is composed of a single crystal of a nitride of a Group 13 metal element. The seed crystal film includes main body parts and thin parts having a thickness smaller than that of the main body parts, and the main body parts and thin parts are exposed to a surface of the seed crystal substrate. The nitride of a Group 13 metal element is grown on the seed crystal film by flux method.

The present invention further provides a seed crystal substrate for growing a nitride of a Group 13 metal element by flux method. The seed crystal substrate includes a supporting body, and a seed crystal film formed on the supporting body and is composed of a single crystal of a nitride of a Group 13 metal element. The seed crystal film includes main body parts and thin parts having a thickness smaller than that of the main body parts, and the main body parts and thin parts are exposed to a surface of the seed crystal substrate.

According to the present invention, when a nitride of a Group 13 metal element is produced by flux method using a seed crystal substrate, the growth defects of the nitride of a Group 13 metal element can be prevented and the grown nitride of a Group 13 metal element can be easily separated from the supporting body.

### BRIEF DESCRIPTION OF THE DRAWINGS

FIGS. 1(a), (b), (c) and (d) are drawings schematically showing steps in a production method according to a comparative example.

FIGS. 2(a), (b), (c) and (d) are drawings schematically showing steps in a production method according to an example of the present invention.

FIG. 3 is a view schematically showing a seed crystal substrate 10 according to an embodiment of the present invention.

FIG. 4 is a photograph taken by an optical microscope and showing a peeled surface of gallium nitride single crystal, according to example 1.

FIG. 5 is a photograph taken by a fluorescence microscope and showing a peeled surface of gallium nitride single crystal, according to example 1.

FIG. 6 is a diagram illustrating an area for measurement in example 1.

FIG. 7 is a diagram illustrating the state of crack generation in examples.

FIG. 8 is a diagram illustrating the state of growth defects in the comparative example.

FIG. 9 is a diagram illustrating the state of crack generation in the comparative example.

FIG. 10 is a graph showing relationship between a thickness of thin parts made of gallium nitride single crystal and a full width at half maximum of X-ray diffraction chart.

### EMBODIMENTS OF THE INVENTION

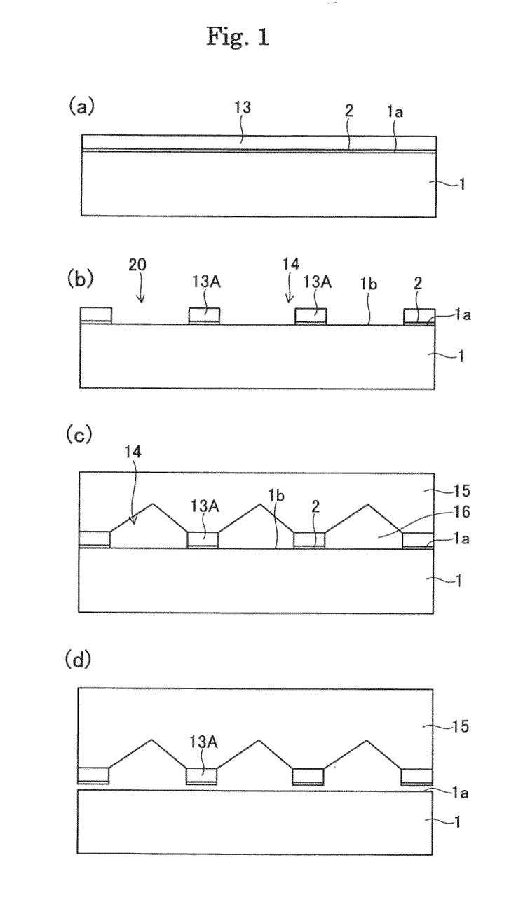

According to a comparative example of FIG. 1, as shown in FIG. 1(a), a low temperature buffer layer 2 made of, for example, a nitride of a Group 13 metal element, is formed on a surface 1a of a supporting body 1. A seed crystal film 13 made of a single crystal of a nitride of a Group 13 metal element is then formed on the low temperature buffer layer 2.

A resist is then formed on the seed crystal film 13, patterned and removed to form a plurality of seed crystal layers 13A separated from one another, as shown in FIG. 1(b). Spaces 14 are formed between the adjacent seed crystal layers 13A, and a surface 1a of the supporting body is exposed in the spaces 14. 1b represents an exposed surface.

On the thus obtained seed crystal substrate 20, as shown in FIG. 1(c), a nitride 15 of a Group 13 metal element is epitaxially grown by flux method. At this time, the nitride 15 of a Group 13 metal element grows so as to connected with each other across the gaps 14 between the seed crystal films 13A to form an integrated layer. Thereafter, upon cooling, as shown in FIG. 1(d), the nitride 15 of a Group 13 metal element is peeled off from the supporting body 1 along the low temperature buffer layer 2.

According to the present example, a material of the supporting body 1, such as sapphire, is exposed in the gaps 14 between the seed crystal films 13A, so that spaces 16 can be easily formed over the gaps 14 and the grown single crystal is easily separated from the supporting body due to the spaces. It was, however, the tendency of generation of many growth defects in the nitride of a Group 13 metal element.

On the other hand, according to the structure that the supporting body 1 is not exposed in the gaps 14 between the seed crystal films 13A and instead the buffer layer or polycrystalline film are exposed to the gaps 14, gallium nitride single crystal tends to be grown from the gaps 14 and the spaces thereby tend to be not generated under the single crystal. It is thus difficult to separate the grown single crystal from the supporting body.

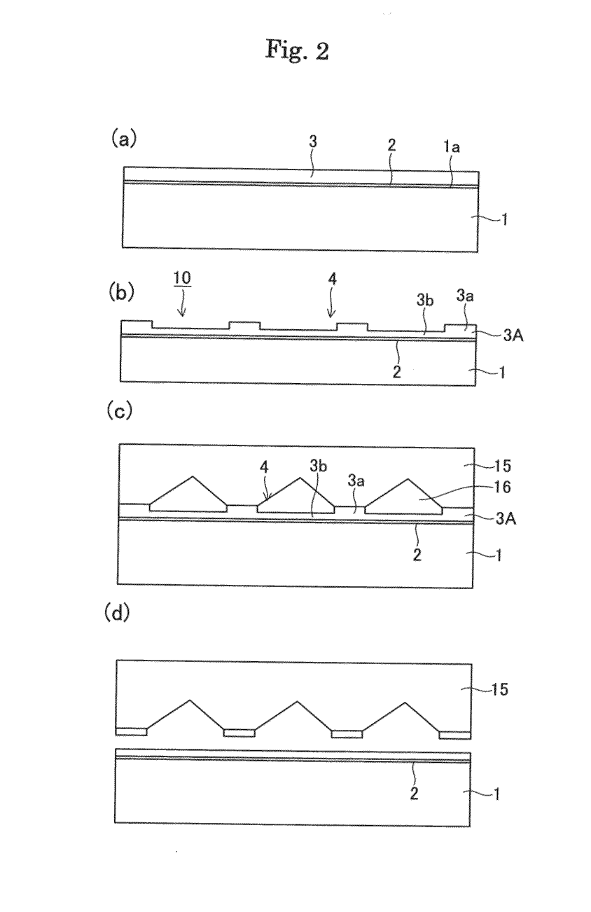

FIGS. 2(a) to (d) schematically show steps of production method according to the inventive embodiment.

As shown in FIG. 2(a), a low temperature buffer layer 2, for example made of a nitride of a Group 13 metal element, is formed on a surface of a supporting body 1. A seed crystal film 3 made of a single crystal of a Group 13 metal element is formed on the low temperature buffer layer 2.

A resist is then formed on the seed crystal film 3, patterned and removed. Here, during the patterning, as shown in FIG. 2(b), main body parts 3a and thin parts 3b are formed in the seed crystal film 3A. That is, parts covered with the resist during the etching or the like are left as main body parts, and at the same time, the seed crystal film is left also in parts which are not covered by the resist to leave the thin parts. The thin parts 3b are thereby left between the adjacent main body parts 3a so that the surface 1a of the supporting body 1 is not exposed. According to the present example, recesses are formed over the thin parts 3b, respectively.

On the thus obtained seed crystal substrate 10, as shown in FIG. 2(c), the nitride 15 of a Group 13 metal element is epitaxially grown by flux method. At this time, it is proved that the nitride 15 of a Group 13 metal element is grown so as to be connected with each other across the recesses 4 between the main body parts 3a to form an integrated layer. At this time, upon cooling, as shown in FIG. 2(d), it is proved that the nitride 15 of a Group 13 metal element is peeled off from the supporting body 1.

According to the present example, the growth defects of the nitride 15 of a Group 13 metal element are prevented and the single crystal of the nitride of a Group 13 metal element is generated over a wide area. It is proved that the single crystal of the nitride of a Group 13 metal element is epitaxially grown mainly on the main body parts 3a and that the crystal is epitaxially grown thereon easier than on the thin parts.

At the same time, it is further proved that the supporting body 1 is not exposed from the seed crystal film 3A and that the spaces 16 tend to be generated under the grown single crystal of the nitride of a Group 13 metal element. The grown nitride single crystal of a Group 13 metal element is thereby easily separated from the supporting body.

The supporting body 1 is not particularly limited as far as a nitride of a Group 13 element can be grown. It includes sapphire, silicon single crystal, SiC single crystal, MgO single crystal, ZnO single crystal, spinel (MgAl₂O₄), LiAlO₂, LiGaO₂, and perovskite composite oxides such as LaAlO₃, LaGaO₃ and NdGaO₃. Also, it is possible to use cubic perovskite structure composite oxides represented by the composition formula [A_{1-y}(Sr₁₋ₓBaₓ)_{y}] [(Al_{1-z}Ga_{z})₁₋ᵤ·Dᵤ]O₃ (where A is a rare-earth element, D is one or more elements selected from the group consisting of niobium and tantalum, y=0.3 to 0.98, x=0 to 1, z=0 to 1, u=0.15 to 0.49, and x+z=0.1 to 2). In addition, SCAM (ScAlMgO₄) may be also used.

The nitride of a Group 13 metal element forming the low temperature buffer layer or seed crystal film and the nitride of a Group 13 metal element formed thereon may preferably be a nitride of one or more metal selected from the group of Ga, Al and In, and more preferably be GaN, AlN, AlGaN or the like. Further, these nitrides may contain unintended impurity elements. Further, for controlling the conductivity, it may contain a dopant, intentionally added, such as Si, Ge, Be, Mg, Zn, Cd or the like.

The wurtzite-type structure of the nitride of a Group 13 metal element includes c-face, a-face and m-face. Each of these crystalline faces are defined based on crystallography. The low temperature buffer layer, intermediate layer, seed crystal layer and gallium nitride single crystal grown by flux method may be grown in the direction normal with respect to c-face, or the direction normal with respect to a non-polar face, such as a-face and m-face, and a semi polar face, such as R-face.

The low temperature buffer layer and seed crystal film may preferably be formed by a vapor growth method including metal organic chemical vapor deposition (MOCVD), hydrid vapor phase epitaxy (HYPE), pulse-excited deposition (PXD), MBE and sublimation techniques. Organic metal chemical vapor deposition is most preferred.

The thickness of the low temperature buffer layer is not particularly limited, and may preferably be 10 nm or larger, and preferably be 500 nm or smaller and more preferably be 250 nm or smaller.

On the viewpoint of facilitating the peeling of the single crystal from the supporting body, it is preferred that the growth temperature of the seed crystal film is higher than that of the low temperature buffer layer. The temperature difference may preferably be 100° C. or larger and more preferably be 200° C. or larger.

The growth temperature of the low temperature buffer layer may preferably be 400° C. or higher, more preferably be 450° C. or higher, and preferably be 750° C. or lower and more preferably be 700° C. or lower. The growth temperature of the seed crystal film may preferably be 950° C. or higher and more preferably be 1050° C. or higher, and preferably be 1200° C. or lower and more preferably be 1150° C. or lower.

In the case that the seed crystal film of gallium nitride is produced by organic metal vapor phase deposition, the raw materials may preferably be trimethyl gallium (TMG) and ammonia.

As the low temperature buffer layer is formed at a relatively low temperature as described above, the component of the low temperature buffer layer may be evaporated during the subsequent growth of the seed crystal layer to leave spaces within the low temperature buffer layer. In this case, the crystal quality of the seed crystal film may be deteriorated so that the crystal quality of the single crystal of a Group 13 metal element may be subjected to deterioration. Therefore, according to a preferred embodiment, after the low temperature buffer layer is formed, it is formed a layer of preventing evaporation for preventing the evaporation of components of the low temperature buffer layer 2. It is thereby possible to prevent the formation of spaces within the low temperature buffer layer during the growth of the seed crystal layer and to prevent the deterioration of the crystal quality of the seed crystal layer. The material of such layer of preventing evaporation includes GaN, AlN, AlGaN or the like.

The layer of preventing evaporation may be grown according to vapor phase process as described above. The growth temperature of the layer of preventing evaporation may preferably be 400 to 900° C. The difference between the growth temperature of the layer of preventing evaporation and that of the intermediate layer may preferably be 0 to 100° C.

According to the present embodiment, more preferably, the material of the low temperature buffer layer is InGaN, InAlN or InAlGaN, and the component susceptible to evaporation is In. Then, the material of the layer of preventing evaporation is GaN, Aln or AlGaN. Such layer of preventing evaporation can be easily formed by terminating the supply of only In raw material gas during the formation of InGaN, InAlN or InAlGaN.

Further, in the case that the low temperature buffer layer is composed of a super lattice structure, it is possible to give the function as the layer of preventing evaporation to thin layers in the super lattice structure, so that it is possible to prevent the formation of the spaces within the intermediate layer. In this case, the layer of preventing evaporation is not necessary.

The low temperature buffer layer is not indispensable according to the present invention, and it is possible to facilitate the peeling of the nitride of a Group 13 metal element in the case that the low temperature buffer layer is not present.

According to the present invention, the seed crystal film includes the main body parts having a relatively large thickness and the thin parts having a relatively small thickness, and the main body parts and thin parts are exposed to a surface of the seed crystal substrate.

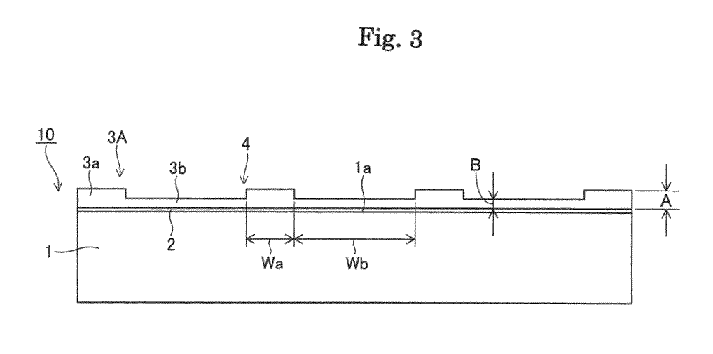

That is, for example as shown in FIG. 3, the seed crystal film 3A includes the main body parts 3a having a relatively large thickness “A” and the thin parts 3b having a relatively small thickness “B”, and the main body parts 3a and thin parts 3b are exposed to the surface of the seed crystal substrate 10. An inner face 1a of the supporting body is not exposed to the growing face of the nitride of a Group 13 metal element. Further, on the single crystal film, it was not formed a mask, the buffer layer and the polycrystalline film which do not function as a seed crystal.

The thickness “A” of the main body parts 3a may preferably be 3 μm or larger and more preferably be 5 μm or larger, on the viewpoint of facilitating epitaxial growth of the nitride of a Group 13 metal element by flux method. Further, the thickness “A” of the main body parts 3a may preferably be 10 μm or smaller and more preferably be 8 μm or smaller, on the viewpoint of productivity during the film formation.

The thickness “B” of the thin parts 3b may preferably be 1.5 μm or smaller and more preferably be 1.0 μm or smaller, on the viewpoint of facilitating the peeling of the nitride of a Group 13 metal element. This is because the crystallinity of the thin parts is deteriorated and the spaces can be generated easier over the thin parts as the thin parts are made thinner. The thickness “B” of the thin parts 3b may preferably be 0.5 μm or larger and more preferably be 0.7 μm or larger, on the viewpoint of preventing the growth defects of the nitride of a Group 13 metal element by flux method.

A difference between the thickness “A” of the main body parts and the thickness “B” of the thin parts may preferably be 2 μm or larger and more preferably be 3 μm or larger, on the viewpoint of facilitating the peeling of the nitride of a Group 13 metal element.

The minimum width “Wa” of each main body part 3a may preferably be 600 μm or smaller an more preferably be 400 μm or smaller, on the viewpoint of improving the quality of the single crystal. Further, it may preferably be 10 μm or larger and more preferably be 25 μm or larger, on the viewpoint of stably growing the nitride of a Group 13 metal element.

The minimum width “Wb” of the thin part 3b may preferably be 250 μm or larger and more preferably be 500 μm or larger, on the viewpoint of improving the quality of the single crystal. The distance may preferably be 4000 μm or smaller and more preferably be 3000 μm or smaller, on the viewpoint of facilitating that the single crystals grown from the adjacent main body parts are connected and integrated with each other.

Here, the minimum width of the main body part or thin part means a length of a straight line having the smallest length, among straight lines connecting optional two points on an outline of it. Therefore, in the case that the main body part or thin part has a shape of a band or a stripe, it is the length of the narrow side, in the case that the main body part or thin part has a shape of a circle, it is its diameter, and in the case that the main body part or thin part has a shape of a regular polygon, it is a distance between a pair of opposing sides.

For forming the thin parts in the seed crystal film, the following methods may be listed, for example. The seed crystal film 3 with a constant thickness is formed first, and a resist is formed and patterned with etching. The method of etching includes the followings.

Dry etching using a chlorine-based gas (RIE)

Argon ion milling followed by dry etching (RIE) using a fluorine-based gas

According to this embodiment, chlorine and fluorine tend to be adsorbed on the thin parts and remained. These elements are contained in etchants. In this case, the amount of chlorine was 0.1 to 0.5 atm/% and the amount of fluorine was 0.1 to 0.5 atm/%, respectively. These amounts may be measured by means of XPS (X-ray photoelectron spectroscopy).

Then, preferably, the seed crystal substrate is subjected to thermal treatment (annealing). Atmosphere for this may preferably be an inert atmosphere and particularly preferably nitrogen atmosphere having a low residual oxygen partial pressure. The temperature may preferably be 300 to 750° C.

According to the present invention, the nitride of a Group 13 metal element is grown on the seed crystal film by flux method.

Raw materials forming the flux are selected depending on the target single crystal of the nitride of a Group 13 metal element.

Raw materials for gallium include gallium pure metal, gallium alloy and gallium compound, and gallium pure metal is preferred on the viewpoint of handling.

Raw materials for aluminum include aluminum pure metal, aluminum alloy and aluminum compound, and aluminum pure metal is preferred on the viewpoint of handling.

Raw materials for indium include indium pure metal, indium alloy and indium compound, and indium pure metal is preferred on the viewpoint of handling.

The growth temperature of the single crystal of the nitride of a Group 13 element and holding time for the growth in the flux method are not particularly limited, and appropriately adjusted depending on the kind of the target single crystal and composition of flux. For example, in the case that gallium nitride single crystal is grown using flux containing sodium or lithium, the growth temperature may be made 800 to 1000° C.

According to flux method, the single crystal is grown under gas atmosphere containing molecules including nitrogen atoms. Although the gas may preferably be nitrogen gas, it may be ammonia. Although the total pressure of the atmosphere is not particularly limited, on the viewpoint of preventing evaporation of flux, it may preferably be 1 MPa or higher and more preferably be 3 MPa or higher. However, as the pressure becomes higher, the system tends to be larger, and the total pressure may preferably be 200 MPa or lower and more preferably be 50 MPa or lower. Although a gas other than nitrogen in the atmosphere is not limited, it may preferably be an inert gas and more preferably be argon, helium or neon.

### EXAMPLES

### Example 1

Gallium nitride single crystal was grown according to the method described referring to FIGS. 2 and 3.

Specifically, it was prepared a so-called GaN template in which a seed crystal layer 3 with a thickness of 5 μm and composed of gallium nitride single crystal was epitaxially grown by MOCVD method on a surface of a c-face sapphire body 1 having a diameter of 3 inches. In a central region of φ54 mm of the surface of the template, stripe-shaped Ni thin films (resists) each having a width of 0.05 mm were formed by electron beam deposition at a period of 0.55 mm. The thickness of the Ni thin film was made 4000 angstroms. At this time, the direction of each stripe was made parallel with the direction of a-axis (11-20) of sapphire forming the supporting body 1. The seed crystal film 3 was dry-etched by using ICP-RIE system and chlorine gas to a depth of 4 μm. Thereafter, the Ni thin films were removed using commercial etchant. The substrate was then washed using buffered fluoric acid and subjected to annealing at 700° C. for 20 minutes in a nitrogen atmosphere furnace to obtain a seed crystal substrate 10 as shown in FIG. 2(b).

Then, by flux method, gallium nitride single crystal 15 was grown on the seed crystal substrate 10. Specifically, it was used a cylindrical crucible with a flat bottom having an inner diameter of 80 mm and a height of 45 mm, and raw materials for the growth (Ga metal 60 g, Na metal 60 g, carbon 0.15 g) were molten and filled in the crucible in a glove box. Na was filled first, and Ga was then filled so that Na is shielded from atmosphere to prevent the oxidization. The height of the melt of the raw materials in the crucible was about 15 mm. After the crucible was contained and sealed in a container made of a heat-resistant metal, the container was mounted on a table, in a crystal growth furnace, which can be rotated and shaken. After the temperature was raised to 870° C. and pressure was raised to 4.5 MPa, it was held for 100 hours while the solution was agitated by shaking and rotating to perform the crystal growth. Thereafter, the temperature was cooled to room temperature over 10 hours and the crystal was collected. The thus grown crystal was GaN crystal 15 of about 1.5 mm over the whole surface of the seed crystal substrate of about 2 inches. The deviation of thickness in plane was small and less than 10 percent.

After the flux was removed using ethanol, the thus grown GaN could be peeled off form sapphire only by weak touch with hands. Cracks were not observed in both of GaN and sapphire by visual evaluation.

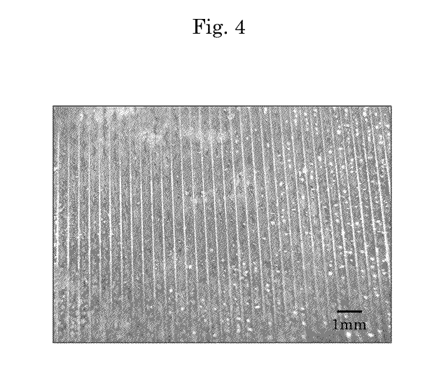

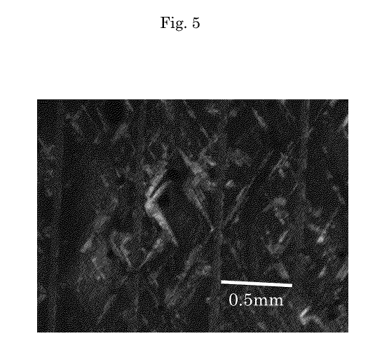

The peeled back face was observed to prove that spaces were formed as shown in FIG. 4. The heights of the spaces were about 100 to 200 μm. It was further observed using a fluorescent microscope to prove that yellow luminescence was observed on the stripe parts and it was confirmed that the GaN film formed by MOCVD method was adhered onto the LPE-GaN (FIG. 5). Further, yellow luminescence was observed over the whole surface of sapphire and it was confirmed that the GaN film formed by MOCVD method was left also on the side of sapphire. Therefore, as shown in FIG. 2(d), it is speculated that the peeling occurred within the seed crystal film.

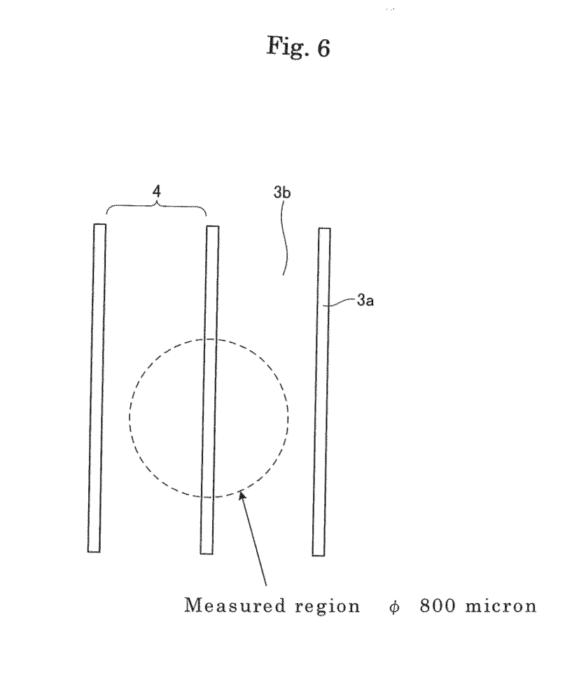

As a result of XPS analysis of the seed crystal substrate belonging to another lot, trace amounts of fluorine and chlorine were detected in a region of φ800 μm including the stripes. FIG. 6 schematically shows the observed region. The results were further shown in table 1.

TABLE 1
Semi-quantitative measurement by XPS

atom %

| | C1s | N1s | O1s | F1s | Na1s | Al2p | Cl2p | Ga2p3 | Total |
|---|---|---|---|---|---|---|---|---|---|
| Mg K α ray | 23.3 | 0.8 | 41.8 | 0.1 | | 33.0 | 0.1 | 1.1 | 100.1 |
| Monochromatic | 18.7 | 0.8 | 49.5 | 0.1 | | 29.1 | 0.1 | 1.7 | 100.1 |
| Al K α ray | | | | | | | | | |

### Example 2

The experiment of growing gallium nitride single crystal was performed according to the same procedure as the Example 1.

According to the present example, however, the thickness “A” of the main body parts, the thickness “B” of the thin parts, and dimension of the step (A-B) were changed. The results were shown in table 2.

TABLE 2

| | | | | Presence or | |
|---|---|---|---|---|---|
| | | | | absence of | |
| | | | Thickness of | peeling over | Presence or |
| A | B | A − B | grown crystal | whole surface | Absence of |
| (μm) | (μm) | (μm) | (μm) | of sapphire | Cracks |
| 5 | 0.5 | 4.5 | 1.2~1.5 | Present | Three lines |
| 8 | 1 | 7 | 1.3~1.9 | Present | Two lines |
| 8 | 0.5 | 7.5 | 1.6~2.3 | Present | Five lines |
| 5 | 1.5 | 3.5 | 1.0~1.5 | Present | None |
| 3 | 1 | 2 | 1.1~1.9 | Present | Two lines |

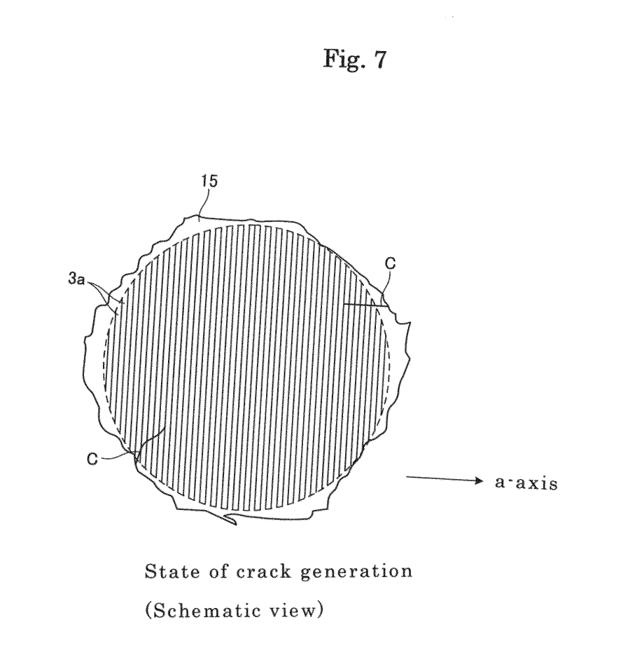

In all the cases, GaN crystal was grown in a thickness of about 1.5 μm. Cracks were not present in one example, and several lines of small cracks were generated in the remaining ones, and the underlying sapphire body was peeled off over the whole surface in each. FIG. 7 schematically shows the state of generation of cracks “C”. Cracks of about 1 cm were generated in the outer region of each. All of the five were subjected to cylindrical grinding to obtain self-standing substrates each of φ1 inch.

### Comparative Example 1

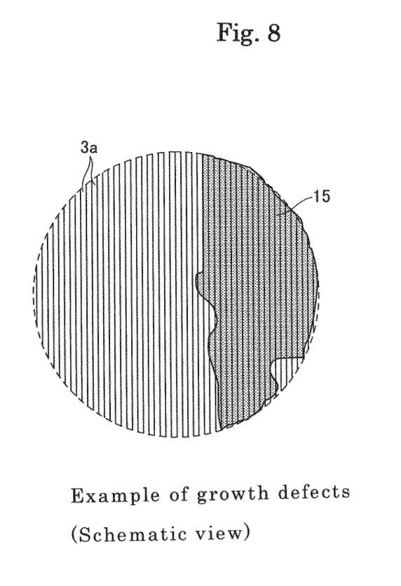

The experiment of growing gallium nitride single crystal was performed according to the same procedure as the Example 1, except that the thickness “B” of the thin parts was made zero to expose the surface of the supporting body. As a result, growth defects frequently occurred during the growth of the nitride of a Group 13 metal element. FIG. 8 shows the schematic view. The results were further shown in table 3.

TABLE 3

| | | | | Presence or | |
|---|---|---|---|---|---|
| | | | | Absence of | |
| | | | | peeling of | Presence or |
| A | B | A − B | Thickness of | sapphire over | Absence of |
| (μm) | (μm) | (μm) | Grown crystal | whole surface | Cracks |
| 3 | 0 | 3 | Not grown | Present | — |
| 5 | 0 | 5 | Grown over | Present | Two lines |
| | | | about a half | | |
| | | | region | | |
| 5 | 0 | 5 | Grown over | Present | Three lines |
| | | | about a half | | |
| | | | region | | |
| 8 | 0 | 8 | Not grown | Present | — |
| 8 | 0 | 8 | Grown in only | Present | One line |
| | | | a part | | |

As described above, the in-plane deviation was large and fluorine and chlorine were detected by the XPS analysis of the region where sapphire is exposed. It is thus considered that residue of the RIE processing or components of the washing agent remained on the sapphire body would be one of the cause. It is considered that there is not the dependency on the thickness “A” or dependency on the thickness (A-B).

Although it could be produced a substrate of a rectangular shape of 10×15 mm from the thus obtained crystal, it could not be produced a self-standing wafer of φ1 inch.

### Comparative Example 2

Gallium nitride single crystal was grown according to the method described in Japanese Patent Publication No. 2010-163288A. That is, a surface of a supporting body was patterned to form pattern including protrusions, a seed crystal film composed of gallium nitride single crystal was formed on the protrusions, a polycrystalline film was formed in recesses between the protrusions, and gallium nitride single crystal was grown on the seed crystals by flux method.

Specifically, on a surface 1a of a c-face sapphire body 1 with a diameter of 2 inches, many grooves were formed each having a depth of 25 μm and a width of 0.5 mm at a period of 0.7 mm. At this time, the direction of the groove was made parallel with the direction of a-axis (11-20) of sapphire. The recesses were formed by a dicer (with a diamond blade of No. #400). Seed crystal films made of gallium nitride single crystal were epitaxially grown on the substrate main body to obtain a template substrate. That is, the film-forming face was oriented in a-face, that is (11-20) face of the GaN seed crystal. However, GaN was polycrystalline at wall surfaces of the recesses.

Gallium nitride single crystal 6 was then grown on the template substrate by flux method. The growing method was made same as that in the Example 1.

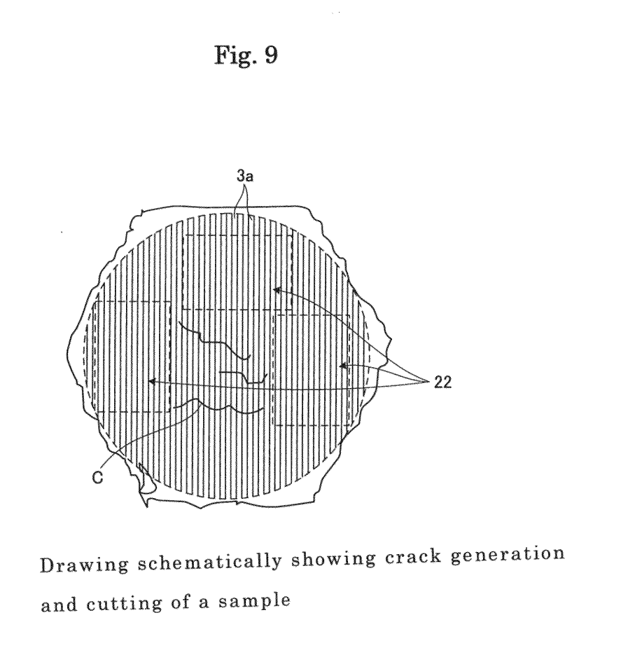

Although the grown crystal could be peeled off from sapphire, cracks were frequently generated in the sapphire body. In the case that cracks were generated in the sapphire body, the cracks were transmitted to the grown GaN crystal. The cracks were often generated in the central region of the grown crystal as schematically shown in FIG. 9. It was thus necessary to cut it out as a rectangular block as shown in FIG. 9, for example, so that only a rectangular substrate of about 10×15 mm could be produced.

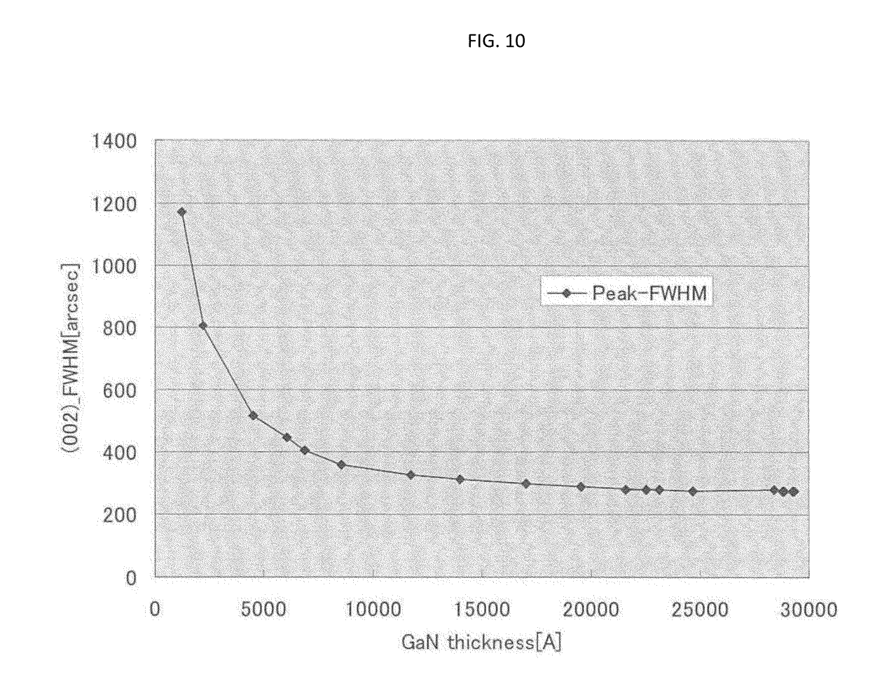

Next, the dependency of the crystallinity on the thickness of the thin part is shown (FIG. 10). As the thickness of the thin part is smaller, the crystallinity tends to be deteriorated. Particularly, as the thin part becomes thinner that 0.5 μm, it was proved that the crystallinity was considerably deteriorated. As GaN is molten back into the flux in a thickness of 0.5 μm during the time period that nitrogen is not saturated, by making the thickness “B” of the thin part to 1.5 μm or smaller and more preferably 1.0 μm or smaller, the thin part is thinned before the initiation of the growth so that the crystallinity of the “B” part is deteriorated and spaces tend to be generated on the thin parts.

Although the present invention has been described with reference to particular embodiments, the invention is not limited thereto and various changes and modification may be made without departing from the scope of the appended claims.

1. A method of producing a nitride of a Group 13 metal element by flux method using a seed crystal substrate, said seed crystal substrate comprising:
a supporting body; and
a seed crystal film formed on said supporting body and comprising a single crystal of a nitride of a Group 13 metal element;
wherein said seed crystal film comprises main body parts and thin parts having a thickness smaller than that of said main body parts, and
wherein said main body parts and said thin parts are exposed to a surface of said seed crystal substrate, the method comprising the step of growing said nitride of a Group 13 metal element on said seed crystal film by flux method.

2. The method of claim 1, wherein recesses are formed over said thin parts, respectively, on a surface of said seed crystal film, and wherein steps are formed between said main body parts and said thin parts, respectively.

3. The method of claim 1, wherein said thin parts have a thickness of 1.5 μm or smaller.

4. The method of claim 1, wherein said seed crystal substrate comprises a low temperature buffer layer provided between said seed crystal film and said supporting body, said low temperature buffer layer comprising a nitride of a Group 13 metal element.

5. The method of claim 1, wherein chlorine and fluorine atoms are adsorbed on said thin parts.

6. The method of claim 1, wherein said nitride of a Group 13 metal element grown by flux method comprises gallium nitride.

7. A seed crystal substrate for growing a nitride of a Group 13 metal element by flux method, said seed crystal substrate comprising:
a supporting body; and
a seed crystal film formed on said supporting body and comprising a single crystal of a nitride of a Group 13 metal element;
wherein said seed crystal film comprises main body parts and thin parts having a thickness smaller than that of said main body parts, and
wherein said main body parts and said thin parts are exposed to a surface of said seed crystal substrate.

8. The seed crystal substrate of claim 7, wherein recesses are formed over said thin parts, respectively, on a surface of said seed crystal film, and wherein steps are formed between said main body parts and said thin parts, respectively.

9. The seed crystal substrate of claim 7, wherein said thin parts have a thickness of 1.5 μm or smaller.

10. The seed crystal substrate of claim 7, further comprising a low temperature buffer layer provided between said seed crystal film and said supporting body, said low temperature buffer layer comprising a nitride of a Group 13 metal element.

11. The seed crystal substrate of claim 7, wherein chlorine and fluorine atoms are adsorbed on said thin parts.
